(19) United States
(12) Patent Application Publication
(10) Pub. No.: US 2026/0118778 A1
(43) Pub. Date: Apr. 30, 2026

(54) METHOD FOR INCORPORATING TEMPERATURE-REGULATING HOLLOW STRUCTURES INTO A SUBSTRATE, IN PARTICULAR INTO A SUBSTRATE FOR AN OPTICAL ELEMENT FOR AN EUV PROJECTION EXPOSURE APPARATUS, AND PROCESSING SYSTEM THEREFOR, METHOD AND SUBSTRATE FOR PRODUCING AN OPTICAL ELEMENT, OPTICAL ELEMENT, AND SEMICONDUCTOR TECHNOLOGY APPARATUS

(71) Applicant: Carl Zeiss SMT GmbH, Oberkochen (DE)

(72) Inventors: Caren MOELLER, Oberkochen (DE); Erik LOOPSTRA, Oberkochen (DE); Samer SULEIMAN, Oberkochen (DE); Andreas SEIFERT, Oberkochen (DE); Martin TIMM, Oberkochen (DE); Sebastian FAAS, Oberkochen (DE); Joachim RUCK, Oberkochen (DE)

(21) Appl. No.: 19/419,865

(22) Filed: Dec. 15, 2025

Related U.S. Application Data
(63) Continuation of application No. PCT/EP2024/065182, filed on Jun. 3, 2024.

(30) Foreign Application Priority Data
Jun. 14, 2023 (DE) 10 2023 205 563.5

(51) Int. Cl. G03F 7/00; B23K 26/354; G01N 21/33; G01N 21/95; G01N 21/956; G02B 7/18

(52) U.S. Cl. CPC G03F 7/70891; B23K 26/354; G01N 21/33; G01N 21/9501; G01N 21/956; G02B 7/1815; G03F 7/70233; G03F 7/70316; G03F 7/70958; G01N 2021/95676; G01N 2201/0636

(57) ABSTRACT

A method for incorporating temperature-regulating hollow structures into a substrate of an optical element, comprising: (A) providing a substrate consisting of a substrate material 12a; (B) progressively focusing a processing light beam onto processing locations at which temperature-regulating hollow structures are intended to arise, so that the substrate material 12a is ablated at the processing locations, wherein adjacent to the processing locations modified substrate material arises, having an increased etching susceptibility relative to the substrate material 12a; (C) applying a rinsing fluid to the processing locations while step (B) is carried out, whereby ablated substrate material is rinsed away. In a step (D), an etching medium is applied to the processing locations while step (B) is carried out, wherein the etching medium removes modified substrate material present there by way of an etching process.

### CROSS REFERENCE TO RELATED APPLICATIONS

This is a Continuation of International Application PCT/EP2024/065182, which has an international filing date of Jun. 3, 2024, and which claims the priority of German Patent Application 10 2023 205 563.5, filed Jun. 14, 2023. The disclosures of both applications are incorporated in their respective entireties into the present Continuation by reference.

### INTRODUCTION

### 1. Field

The techniques disclosed herein relate to a method for incorporating temperature-regulating hollow structures into a substrate, in particular into a substrate for an optical element, such as a mirror for an EUV projection exposure apparatus, comprising the following steps:
(A) providing a substrate consisting of a substrate material;
(B) progressively focusing a processing light beam onto processing locations at which temperature-regulating hollow structures are intended to arise, so that the substrate material is ablated at the processing locations, wherein adjacent to the processing locations modified substrate material arises, having an increased susceptibility to a chemically active treatment medium relative to the substrate material; and
(C) applying a rinsing fluid to the processing locations while step (B) is carried out, whereby ablated substrate material is rinsed away.

In addition, the disclosed techniques relate to, for carrying out this method, a processing system for incorporating temperature-regulating hollow structures into a substrate, in particular into a substrate for an optical element, such as a mirror for an EUV projection exposure apparatus, comprising:
a) a light source, by which a processing light beam is generated;
b) a focusing device by which the processing light beam is focusable onto processing locations at which temperature-regulating hollow structures are intended to arise, so that the substrate material is ablated at the processing locations, wherein adjacent to the processing locations modified substrate material arises, having an increased etching susceptibility relative to the substrate material; and
c) a fluid device by which a rinsing fluid is able to be applied to the processing locations, whereby ablated substrate material is rinsed away.

Furthermore, the disclosed techniques relate to a method for producing an optical element, in particular for producing a mirror for an EUV projection exposure apparatus.

The techniques disclosed herein further relate to a substrate for producing an optical element, in particular for producing a mirror for an EUV projection exposure apparatus, wherein the substrate has temperature-regulating hollow structures, and also relates to an optical element, in particular a mirror for an EUV projection exposure apparatus with a substrate, as well as to a semiconductor technology apparatus and a structured electronic component.

The following description of the disclosed techniques is given on the basis of an optical element in the form of a mirror and the use thereof in an EUV projection exposure apparatus, wherein heat is dissipated from the mirror by a temperature-regulating fluid in the form of a cooling fluid being caused to flow through the temperature-regulating hollow structures present in said mirror.

In principle, however, the following explanations apply generally to optical elements which can be assigned a substrate composed of a substrate material into which temperature-regulating hollow structures are incorporated, through which a temperature-regulating fluid can be caused to flow for temperature compensation during operation of the optical element.

In particular, optical elements are used in semiconductor technology apparatuses in which an object is irradiated with a working radiation with the aid of one or more optical elements. Besides an EUV projection exposure apparatus, such semiconductor technology apparatuses include, in particular, mask inspection apparatuses and wafer inspection apparatuses.

On the one hand, temperature regulation may be cooling or heating of the optical element or of at least one area of the optical element. That is to say that, with the aid of the temperature-regulating fluid, the optical element as a whole or at least in a volume region is brought to a temperature which it was not at previously.

On the other hand, however, temperature regulation may also have the effect that a specific temperature or a specific temperature range of the optical element or of at least one region of the optical element is or stays maintained.

These considerations furthermore generally apply to components comprising a corresponding substrate which carries or can carry one or more functional units and into which temperature-regulating hollow structures are incorporated, through which a temperature-regulating fluid can be caused to flow for temperature regulation during operation of the component. Such a component may for example provide a sensor device; in this case, the substrate carries sensor units as functional units.

### 2. Background

Microlithographic projection exposure apparatuses are used in chip production in order to transfer structures on a mask to a photoresist that has previously been applied to a wafer. For this purpose, the mask is illuminated with light and imaged onto the light-sensitive layer in a reduced size. In EUV projection exposure apparatuses, the light has a wavelength of between approximately 5 nm and approximately 30 nm; the commercially available apparatuses use light with a wavelength of 13.5 nm.

However, there are no optical materials which have a sufficiently high transmissivity for such short wavelengths. Therefore, in EUV projection exposure apparatuses, the lens elements that have been customary at longer wavelengths are replaced by mirrors and for this reason the mask also contains a pattern of reflective structures.

The provision of mirrors for EUV projection exposure apparatuses is technologically demanding. The substrate consists of a substrate material, which is generally glass, e.g., quartz glass, titanium-doped quartz glass such as ULE®, or a glass ceramic. Suitable glass ceramics are offered under the trade names Clearceram® or Zerodur® and have the property of having a very low coefficient of thermal expansion at the operating temperature of the mirror 10.

A coating which reflects the EUV light and consists of a multiplicity of thin double layers having alternating refractive indices is applied to the substrate.

Even with such complexly constructed coatings, however, the reflectivity of the mirrors for the EUV light is rarely more than 70%, and even this is only for light which impinges on the reflective coating with normal incidence or with angles of incidence of a few degrees. The portion of the EUV light which is not reflected by the coating is absorbed in the substrate, where it leads to considerable heating since the EUV light sources used are very powerful. Even if glass ceramics having low coefficients of thermal expansion are used, the heating may lead to unacceptable changes in shape of the mirrors.

It has therefore been proposed to provide the substrates with temperature-regulating hollow structures, which in this case are cooling hollow structures, wherein in particular temperature-regulating channels in the form of cooling channels are provided, through which water or some other temperature-regulating fluid, i.e., here a cooling fluid, flows during operation and dissipates heat in this way. Such temperature-regulating channels may have small cross-sectional diameters of the order of magnitude of approximately 1 mm2 and ideally run closely below the reflective coating.

An overview of the hitherto known methods for producing temperature-regulating channels is contained in the application DE 10 2021 214 310.5, filed by the applicant, the disclosure of which is hereby incorporated by reference in its entirety. Particularly promising are methods in which a processing light beam is progressively focused onto processing locations at which temperature-regulating channels are intended to arise.

In that case, the method of the type mentioned in the introduction has become established, in particular, in which the substrate material is ablated by the processing light beam using a processing system of the type mentioned in the introduction and, in the process, ablated substrate material is rinsed away by a rinsing fluid. In that case, a temperature-regulating channel is incorporated into the substrate material proceeding from the surface of the substrate, such that a temperature-regulating channel section that lengthens in the course of the process progressively forms until the desired temperature-regulating channel has been fully incorporated. In general, the externally accessible temperature-regulating channel section is used as a connecting path toward and away from the processing locations. In this method, the modified substrate material arises adjacent to the processing locations, and has a higher etching susceptibility relative to unprocessed substrate material. This modified substrate material arises in particular by way of absorption of the high-energy processing light beam and by way of thermal diffusion of ablated substrate material from the processing locations. In the case of a laser, specialists refer to an area with modified substrate material as a so-called laser affected zone, or LAZ for short. The modified substrate material may also differ relative to the substrate material of the substrate inter alia in terms of density, coefficient of thermal expansion and the material stresses present.

However, such a materially inhomogeneous substrate is not suitable for use in an EUV projection exposure apparatus. Therefore, the modified substrate material must be removed; in the case of the known method, the modified substrate material is etched away in a downstream second step with the aid of an etchant, such as in particular hydrofluoric acid HF or potassium hydroxide KOH.

The process speed overall for the formation of the desired temperature-regulating hollow structure is already limited by the fact that a two-stage process has to be carried out. Primarily the achievable etching rate in the second process stage has a considerable influence on the process speed. In the case of relatively long temperature-regulating hollow structures or temperature-regulating channels, it may happen that the intact substrate material surrounding the hollow structures is attacked by the etchant in an undesirable manner, resulting in conical structures or irregular cross sections in the flow direction. In order to achieve a sufficient material removal rate, the etchant additionally has to be heated frequently; for example, 10 M KOH is used at temperatures of about 90° C. This in turn leads to a risk in the handling of the etchant.

In addition, fluctuations in the microstructure of the substrate material, for example due to areas with different refractive indices/different transmission or due to the formation of thermal lenses, can cause fluctuations in the material removal, which in turn can lead to undesirable deviations in the cross-sectional course of the temperature-regulating hollow structures and roughness on their lateral surfaces.

### SUMMARY

The object of the disclosed techniques is to provide a method and a processing system, a substrate, an optical element and a semiconductor technology apparatus of the kind mentioned in the introduction which take these thoughts into account and by which, in particular, temperature-regulating hollow structures can be incorporated into the substrate with high precision and quality as well as good process speed, so that, using such an optical element, inter alia structured electronic components with significantly small structures can be produced.

In the case of a method of the kind mentioned at the introduction, this object is achieved by the fact that in a step (D) added to the method described in the introduction, a treatment medium is applied to the processing locations while step (B) is carried out, wherein the treatment medium exhibits an effect at the processing locations and removes modified substrate material present there.

Insofar as processing locations in the plural are mentioned hereinafter, this is intended always to clarify the temporal progression during the incorporation of the temperature-regulating hollow structures. In fact, at a particular point in time there is only ever one processing location at the focal point of the processing light beam.

According to the disclosed techniques, it has been recognized that it is possible to remove the resulting modified substrate material as it were at the moment of its formation and to carry out the treatment and thus the attack against the modified substrate material more susceptible to the chemically active treatment medium at the processing locations. In this way, the desired temperature-regulating hollow structure is formed in a single process stage.

The advantages of the features explained below will become clear especially from the description.

The chemically active treatment medium may be an etching medium, an oxidizing agent or a reducing agent and is preferably an etching medium by which in a step (D) added to the method described in the introduction, the modified substrate material (58) is removed by an etching process.

If the chemically active treatment medium is an etching medium, the latter can be coordinated for example expediently in respect of its handleability by virtue of the fact that:
a) the etching medium as such is an etchant;
   or
b) the etching medium is an etchant precursor from which an etchant can arise at the processing locations, and in particular is a temperature-activatable precursor or a reaction-activatable precursor or a photoactivatable precursor.

A precursor is generally less aggressive and less risky to use than an etchant. An etchant arises from a temperature-activatable precursor above a threshold temperature. From a reaction-activatable precursor, the etchant arises by way of a reaction with a reactant. From a photoactivatable precursor, the etchant arises by way of irradiation with an activation radiation. This activation can be effected by the processing light beam.

Preferably, the etching medium is:
a) an etchant in the form of hydrofluoric acid HF or potassium hydroxide KOH;
   or
b) an etchant precursor in the form of potassium hydrogen fluoride HKF₂, ammonium hexafluorosilicate (NH₄)₂[SiF₆], calcium fluoride CaF₂, sodium fluoride NaF, potassium fluoride KF, lithium fluoride LiF, ammonium hydrogen difluoride NH₄HF₂.

Preferably, the chemically active treatment medium, in particular the etching medium, is provided by the rinsing fluid. The physical rinsing by the fluid flow is, in this case, combined with the chemical treatment, in particular the etching, by the chemically active treatment medium entrained by the rinsing fluid.

If the chemically active treatment medium is the etching medium, the alternatives that can be advantageously used are that:
a) the rinsing fluid provides the etching medium as an etchant or as a temperature-activatable etchant precursor from which an etchant arises above a threshold temperature, or as a photoactivatable precursor from which an etchant arises by way of irradiation with an activation radiation;
   or
b) the rinsing fluid is a first rinsing fluid, which provides a reaction-activatable etchant precursor from which etchant can arise at the processing locations by way of a reaction with a reactant, and the reactant is provided by a second rinsing fluid.

It may be expedient if an inert rinsing fluid is additionally applied to the processing locations.

A mixture of fluids, media and materials flows away from the processing locations as a collective fluid, which may also entrain unreacted etchant, inter alia. The latter may attack and negatively alter the material which the already formed section of the desired temperature-regulating hollow structures. Therefore, it is advantageous if collective fluid flowing away from the processing locations is extracted by suction with the aid of a suction extraction device.

Alternatively or supplementarily, collective fluid flowing away from the processing locations can be diluted and/or neutralized with the aid of an auxiliary medium.

In the case of a processing system of the kind mentioned at the beginning, the abovementioned object is achieved by virtue of the fact that the fluid device is configured in such a way that a treatment medium is applied to the processing locations while the focusing device is in operation and the processing light beam is focused onto the processing locations, wherein the treatment medium exhibits an effect at the processing locations and removes modified substrate material present there.

It is correspondingly expedient if the chemically active treatment medium is an etching medium, an oxidizing agent or a reducing agent, wherein an etching medium is preferred by which the modified substrate material is removed by an etching process.

It is particularly advantageous if the treatment medium is an etching medium and:
a) the etching medium as such is an etchant;
   or
b) the etching medium is an etchant precursor from which an etchant can arise at the processing locations, and in particular is a temperature-activatable precursor or a reaction-activatable precursor or a photoactivatable precursor.

Here, too, the etching medium is preferably:
a) an etchant in the form of hydrofluoric acid HF or potassium hydroxide KOH;
   or
b) an etchant precursor in the form of potassium hydrogen fluoride HKF₂, ammonium hexafluorosilicate (NH₄)₂[SiF₆], calcium fluoride CaF₂, sodium fluoride NaF, potassium fluoride KF, lithium fluoride LiF, ammonium hydrogen difluoride NH₄HF₂.

Structurally, it is expedient if the fluid device comprises a conveying section with a feed line, which has a delivery end and is connected to a reservoir in which a rinsing fluid is kept available, which provides the treatment medium. In this case, the feed line is preferably guided through the already formed section of the temperature-regulating hollow structure as far as the treatment locations, which will be explained again further below.

In the present case, a reservoir should be understood to mean in principle any source that provides a material or material mixture.

It may be advantageous that chemically active treatment medium is the etching medium and:
a) the rinsing fluid provides the etching medium as an etchant or as a temperature-activatable etchant precursor from which an etchant arises above a threshold temperature, or as a photoactivatable etchant precursor from which an etchant arises by way of irradiation with an activation radiation;
   or
b) the conveying section is a first conveying section and the rinsing fluid defines a first rinsing fluid, which provides a reaction-activatable etchant precursor from which etchant can arise at the processing locations by way of a reaction with a reactant, and there is a second conveying section with a second feed line, which has a delivery end and is connected to a second reservoir, in which a second rinsing fluid is kept available, which provides the reactant. The fluid device may comprise an inert conveying section with a feed line, which has a delivery end and is connected to a reservoir in which an inert rinsing fluid is kept available.

In order that the delivered fluids also reliably reach the processing locations in the desired manner, it is advantageous that each conveying section present comprises a line conveyor by which the respective delivery end of the feed line is trackable to the processing locations.

With regard to the suction extraction of collective fluid explained above, the fluid device preferably comprises a suction extraction device with a suction extraction line, which has a suction extraction end and is connected to a suction pump, by which collective fluid flowing away from the processing locations is extractable by suction. In this case, it is expedient if the suction extraction device comprises a line conveyor, by which the suction extraction end of the suction extraction line is trackable to the processing locations, in particular at a greater distance from the processing locations than the delivery end(s) of one or more feed lines.

The fluid device may comprise an auxiliary medium conveying section with a feed line, which has a delivery end and is connected to a reservoir in which an auxiliary medium is kept available, in particular an inert rinsing fluid or a neutralizing medium, which can neutralize the treatment medium.

The auxiliary medium conveying section, too, preferably comprises a line conveyor, by which the delivery end of the feed line is trackable to the processing locations, in particular at a greater distance from the processing locations than the delivery end(s) of one or more feed lines of the other conveying sections.

In the case of the method mentioned at the beginning for producing an optical element, in particular for producing a mirror for an EUV projection exposure apparatus, temperature-regulating hollow structures are incorporated into a substrate in accordance with the method explained above and further processing comprises one or more steps of chemical and/or physical processing of at least one surface of the substrate and also creating or applying on the substrate a coating which is designed at least to reflect at least 50% of EUV light impinging with normal or almost normal incidence.

A safe guarantee of good flow properties is also achieved according to the disclosed techniques in the case of a substrate of the kind mentioned at the beginning which defines a carrier surface for a coating in that, with a lifetime of the substrate of up to 10 years, at least up to five years and at least up to two years, the surface figure of the carrier surface changes by less than 100 pm, in particular by less than 50 pm and further in particular by less than 25 pm.

With a lifetime of the optical element of up to 10 years, at least up to five years and at least up to two years, the surface figure of the optical element advantageously changes by less than 100 pm, in particular by less than 50 pm and further in particular by less than 25 pm.

These properties have particularly advantageous effects in the case of a mirror for an EUV projection exposure apparatus, wherein the substrate has a carrier surface which carries a coating which is designed at least to reflect at least 50% of EUV light impinging with normal or almost normal incidence.

In the case of a semiconductor technology apparatus, the object is achieved by such an optical element.

### BRIEF DESCRIPTION OF THE DRAWINGS

Exemplary embodiments of the techniques disclosed herein are explained in greater detail below with reference to the drawings. In these drawings:

FIG. 1 schematically shows a section through an optical element in the form of a mirror for an EUV projection exposure apparatus, which mirror comprises temperature-regulating hollow structures in the form of temperature-regulating channels, through which a cooling fluid is caused to flow by a cooling system;

FIG. 2 shows a processing system used to incorporate temperature-regulating hollow structures into a substrate by a processing light beam;

FIG. 3 shows a part of the processing system according to FIG. 2, wherein the substrate according to the detail B in FIG. 2 is shown on a larger scale and with a result achieved by known methods;

FIGS. 4 to 9 each show a part corresponding to FIG. 3 in the case of processing systems according to the disclosed techniques, each in accordance with one of six exemplary embodiments;

FIG. 10 shows a substrate for an EUV mirror into which temperature-regulating hollow structures have been incorporated;

FIG. 11A shows a topography image of a surface area of a temperature-regulating hollow structure;

FIG. 11B shows a section to illustrate an achieved average roughness Ra;

FIG. 12 schematically shows a longitudinal section of a temperature-regulating hollow structure;

FIG. 13 shows the detail XIII in FIG. 10 on an enlarged scale;

FIG. 14A shows an image of the surface figure of a substrate with intermediate structures before an etching process;

FIG. 14B shows an image of the surface figure of this substrate with temperature-regulating hollow structures obtained after an etching process;

FIG. 14C shows a representation of the differences in the images according to FIGS. 14A and 14B;

FIG. 15 schematically shows a semiconductor technology apparatus on the basis of the example of an EUV projection exposure apparatus.

### DETAILED DESCRIPTION

### 1. Set-Up of an Optical Element on the Basis of the Example of an EUV Mirror

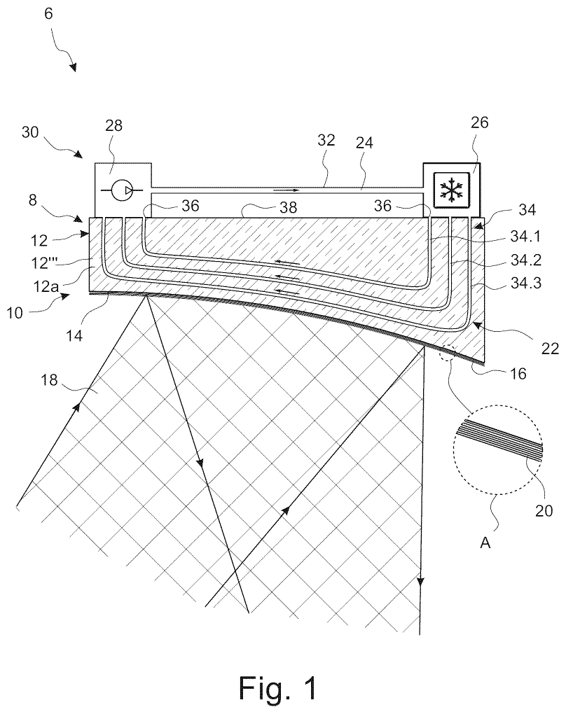

In FIG. 1, a semiconductor technology apparatus explained in the introduction is designated overarchingly by 6 and a section through an optical element designated in its entirety by 8 is shown, which optical element is illustrated by way of example as a mirror 10 for an EUV projection exposure apparatus. The mirror 10 can be arranged there in the illumination system or in the projection lens.

The optical element 8 and thus the mirror 10 comprises a substrate 12 composed of a substrate material 12a, which is therefore a mirror substrate in the case of the present exemplary embodiment of the mirror 10. Such a mirror substrate is in practice a glass ceramic, in particular.

The substrate 12 is monolithic in the case of the present exemplary embodiment, which is also the preferred embodiment. In modifications not shown separately, however, the substrate 12 can also be joined together from partial segments. In principle, additive manufacturing methods are suitable in this case. By way of example, 3D printing methods are also appropriate just like laser welding methods or techniques for the thermal bonding of workpieces.

In the case of the mirror 10, the substrate 12 has a precisely processed surface 14, the curvature of which determines the optical properties of the mirror 10. The surface 14 of the substrate 12 serves as a carrier surface and will also be referred to thus hereinafter. The carrier surface 14 bears a coating 16 ensuring the optical properties of the optical element 8. In the case of the mirror 10 shown here, the coating 16 is configured in such a way that it predominantly reflects incident EUV light 18. As is illustrated in the enlarged detail A, in the case of the present exemplary embodiment, this coating 16 is embodied in multilayer fashion and is constructed in particular from a plurality of double layers 20 which were applied to the carrier surface 14. The coating 16 has a reflection coefficient of at least 50%, preferably of more than 70%, for normal-incidence EUV light 18. The reflectance achieved during operation depends on the angle of incidence of the EUV light 18.

Besides the double layers 20, the coating 16 can comprise further layers, too, which do not contribute to reflection, but optionally to stabilization and/or to protection of the coating 16 or of the optical element 8 or the mirror 10. By way of example, protection against components of a hydrogen plasma can be established in this manner. Such further layers can be provided between the double layers 20 within the coating 16, between the double layers 20 and the carrier surface 14 and/or on the side of the double layers 20 that is remote from the carrier surface 14. In the case of an optical element 8, the coating 16 can also be formed by the outer surface of the substrate 12 being modified by processing and/or treatment. In this case, the coating 16 is therefore not a separately applied coating, but rather defines a layer of the substrate 12 as such; the underlying surface as a transition to the substrate material 12a is then the carrier surface 14. In the case of the mirror 10 explained here and the application of EUV light 18, the unreflected portion enters the substrate 12 and is absorbed there, specifically predominantly in the vicinity of the carrier surface 14. Owing to this absorption, the substrate 12 heats up primarily in the vicinity of the regions of the carrier surface 14 which are exposed to the EUV light 18. Since the coefficient of thermal expansion of the substrate material 12a is not equal to zero and in addition is itself temperature-dependent, the heating up can give rise to changes in shape of the substrate 12 which affect the optical properties of the mirror 10. In relation to optical elements 8, put generally, temperature changes in the substrate 12 can affect the optical properties of the optical element 8.

On account of the extremely tight specifications in EUV projection exposure apparatuses, however, changes in the optical properties of the mirrors therein are unacceptable or acceptable at most to a negligible extent. However, also on a general level again the optical properties are intended to remain stable in the case of optical elements 8 and the functionality is intended to be maintained in the case of components. In order to minimize temperature fluctuations in the substrate material 12a and associated changes in shape of the substrate 12, a plurality of temperature-regulating hollow structures 22 are incorporated into the substrate 12. During the operation of the EUV projection exposure apparatus, a temperature-regulating fluid in the form of a cooling fluid 24 is caused to flow through these temperature-regulating hollow structures 22, cooling water being used in practice; however, other cooling liquids and cooling media are also possible. The cooling fluid 24 absorbs the quantity of heat input by the EUV light 18 and dissipates it from the substrate 12. For this purpose, the temperature-regulating hollow structures 22 are connected to a cooling unit 26 and a pump unit 28 of a cooling system, designated in its entirety by 30. The pump unit 28 sucks up the cooling fluid 24 from the temperature-regulating hollow structures 22 and guides it via a return line 32 to the cooling unit 26. There the cooling fluid 24 is cooled down to its target temperature before it flows through the temperature-regulating hollow structures 22 once again. This circuit is illustrated by corresponding arrows in FIG. 1. The temperature-regulating hollow structures 22 typically run in the vicinity of the carrier surface 14 and at least regionally parallel thereto. In the case of the exemplary embodiments described here, the temperature-regulating hollow structures 22 are formed as temperature-regulating channels 34, of which three temperature-regulating channels 34.1, 34.2 and 34.3 are illustrated. The temperature-regulating channels 34 each extend between two openings 36, which are designated only for the temperature-regulating channel 34.1 in FIG. 1, with each temperature-regulating channel 34 being connected via its openings 36 to the cooling unit 26 and to the pump unit 28. Consequently, depending on assignment, the openings 36 each define an inlet or an outlet of the temperature-regulating channels 34 for the cooling fluid 24. The cross-section of the temperature-regulating channels 34 need not be constant and can be, e.g., circular, oval, rectangular or else ring-shaped. The temperature-regulating hollow structures 22 can have varying cross-sections and shapes depending on the position in the substrate 12. In the case of the present exemplary embodiments, the openings 36 of the temperature-regulating channels 34 are arranged on the rear side 38 of the substrate 12, the opposite side to the carrier surface 14.

In the case of modifications not shown separately, the temperature-regulating hollow structures 22 can also be more extensive chambers in which the cooling fluid 24 is exchanged only slowly and in which no longitudinal axis is defined, as is characteristic of a channel.

Moreover, the arrangement of the temperature-regulating channels 34 illustrated in the figures is merely by way of example and can be different in real systems; the number of temperature-regulating channels 34 can also be larger or smaller. By way of example, the openings 36 can also be arranged at the lateral flanks of the substrate 12 or provision can be made of at least one temperature-regulating channel 34 which runs meanderingly or spirally through the substrate 12 or a part thereof.

In a further modification, it is also possible for one or more temperature-regulating channels 34 to extend proceeding from a distribution section or a distribution chamber in the substrate 12; such temperature-regulating channels 34, with their openings 36, at one end or at both ends, then join such a distribution section or distribution chamber, from which the temperature-regulating channels 34 are then supplied with the temperature-regulating fluid. The distribution section or the distribution chamber and optionally that end of a temperature-regulating channel 34 which is remote therefrom are then correspondingly connected to the cooling system 30.

During the production of an optical element 8 by way of applying the method described here for producing temperature-regulating hollow structures 22, various stages of the substrate 12 are defined.

A first stage of the substrate 12 defines a kind of raw substrate 12′, which is still largely unprocessed and untreated and in which a carrier surface 14 has not yet been formed structurally. In the case of the substrate 12 which is explained above and is a mirror substrate, such a raw substrate is for example a glass parallelepiped composed of glass ceramic.

A second stage of the substrate 12 defines a carrier substrate 12″, in which the carrier surface 14 is produced and formed. This may necessitate a plurality of chemical and/or physical work steps which may comprise processes such as grinding, turning, polishing and/or etching.

A third stage of the substrate 12 then defines an element substrate 12′″, in which the carrier surface 14 is provided at least with the coating 16 determining the optical properties. If the resulting optical element is a mirror, the element substrate 12′″ is thus terminologically a mirror substrate. Accordingly, the substrate 12 in FIG. 1 also bears the reference sign 12′″ since it is shown there in the stage of the element substrate. If the substrate 12 is for example part of a sensor device, as described in the introduction, the element substrate 12′″ is accordingly terminologically a sensor substrate.

The production of the temperature-regulating hollow structures 22 in the substrate 12 described below can take place, in principle, in any stage of the substrate 12. In general, this takes place in the stage of the raw substrate 12′, but can also be carried out for example in the stage of the carrier substrate 12″ or even in the stage of the element substrate 12′″.

In the present case, the production of the temperature-regulating hollow structures 22 is explained in particular on the basis of the example of the carrier substrate 12″ in order to illustrate the function envisaged in the present exemplary embodiment for the mirror 10 obtained later.

### 2. Creating the Temperature-Regulating Hollow Structures on the Basis of the Example of the Temperature-Regulating Channels

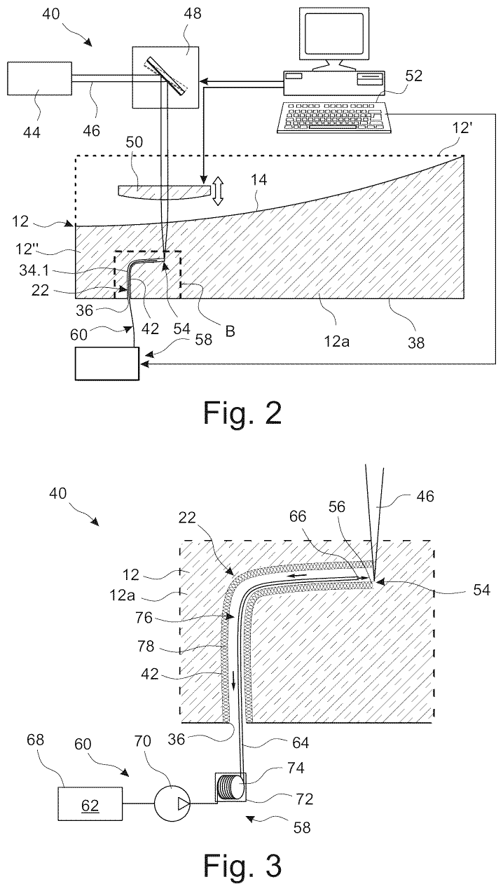

FIG. 2 illustrates the substrate 12 with a dashed outer contour line as the raw substrate 12′ and with solid lines as the carrier substrate 12″, i.e., as the substrate 12 with an already formed carrier surface 14, before the reflective coating 16 is applied.

In addition, only the substrate 12 is denoted in the enlargements of details. The outer contour of the raw substrate 12′ is only partially indicated at the edge in FIG. 10. Also in the raw substrate 12′ the course of the later carrier surface 14 is already fixed, and this then notional carrier surface 14 serves as a reference surface to define the course of the temperature-regulating hollow structures 22 in the substrate 12.

FIG. 2 shows a processing system designated in its entirety by 40, which is used to incorporate the temperature-regulating hollow structures 22 into the substrate 12. Providing such a substrate 12 defines method step (A) mentioned at the beginning.

In this case, the ablation of substrate material 12a is begun at the location of one of the openings 36. This is illustrated on the basis of the example of the temperature-regulating channel 34.1, of which a section of a temperature-regulating hollow structure 22 that has already been incorporated into the substrate 12, and here specifically a temperature-regulating channel section 42, is present, which extends into the substrate 12 proceeding from that opening 36 which forms the outlet to the pump unit 28 in the case of the configuration shown in FIG. 1. Hereinafter in all the exemplary embodiments reference is made to the temperature-regulating channel 34.1 as representative of the other temperature-regulating channels 34 and of generally any type and arrangement of temperature-regulating hollow structures 22.

The processing system 40 comprises a light source 44 that generates a processing light beam 46. The light source 44 is preferably a powerful laser that generates ultrashort pulses. These may be pulses in the femto-, pico- or nanoseconds range. In this case, the processing system 40 realizes a laser ablation system.

The processing light beam 46 can be directed onto different locations of the substrate 12 by a scanning device 48 and a focusing lens element 50, which jointly form a focusing device. The relative arrangement between the substrate 12 and the processing system 40 may also be changed with the aid of a positioning table (not shown) in such a way that the processing light beam 46 can be directed onto any location of the substrate 12 after passing through the focusing lens element 50. The scanning device 48, the focusing lens element 50 and an optionally present positioning table are in this case controlled by a control device 52 in such a way that the processing light beam 46 is progressively focused onto all of the processing locations 54 of the substrate 12 at which temperature-regulating channels 34 are intended to be produced. Alternatively, the relative arrangement between the substrate 12 and the processing system 40 can be changed by positioning the processing system 40. In the case of small substrates 12, movement processes can be dispensed with, provided that the scanning device 48 covers a sufficiently large region.

At the focal points generated by the focusing lens element 50, the intensity of the processing light beam 46 is high enough that the material of the substrate 12 is ablated. In this case, the region in which the processing light beam 46 ablates material defines a respective processing location 54, which by its nature moves concomitantly with the focal point of the processing light beam 46. The locations of the focal points and thus the processing locations 54 determine where a temperature-regulating channel 34 arises in the substrate 12. In order to create a temperature-regulating channel 34 with a sufficiently large cross section, at a certain axial position the processing light beam 46 travels over the entire cross section in the radial direction according to a predetermined pattern. This process is then repeated at respectively adjacent axial positions until the temperature-regulating channel 34 has the desired axial dimension.

In this case, adjacent to the processing locations 54 modified substrate material 56 arises, having in particular an increased susceptibility to a chemically active treatment medium relative to the substrate material 12a of the substrate 12. This is illustrated by FIG. 3, which reproduces on an enlarged scale that detail from the substrate 12 which is delimited by a dashed line and designated by B in FIG. 2.

The formation and properties of the modified substrate material 56 have been explained at the beginning. If this modified substrate material 56 initially arises at a location on which the processing light beam 46 impinges at a later time than the processing location 54, the modified substrate material 56 there is then ablated accordingly.

In summary, method step (B) mentioned at the beginning is defined, in which the processing light beam 46 is progressively focused onto processing locations at which temperature-regulating hollow structures 22 are intended to arise, so that the substrate material 12a is ablated at the processing locations 54, wherein adjacent to the processing locations 54 modified substrate material 56 arises, having an increased etching susceptibility relative to the substrate material 12a.

There is now additionally a fluid device which is designated in its entirety by 58 and is likewise controlled by the control device 52. The fluid device 58 defines a conveying section 60 and applies a rinsing fluid to the processing locations 54 while the substrate material 12a of the substrate 12 is being ablated, whereby ablated substrate material is rinsed away by the rinsing fluid. This defines method step (C) mentioned at the beginning.

In the present case, ablated substrate material should be understood to mean any material or material mixture which has arisen from the substrate material 12a of the substrate 12 at the processing location 54, regardless of the structure or the state of matter.

FIG. 3 supplementarily shows the further components of the fluid device 58 with the conveying section 60, as is implemented in a known method, and the result achieved therewith. In this known method, an inert rinsing fluid 62 is applied to the processing locations 54, and rinses away the substrate material ablated at the processing location 54, but has no reactive action properties. The inert rinsing fluid 62 is generally demineralized water.

The conveying section 60 comprises a flexible feed line 64 with a delivery end 66, via which the inert rinsing fluid 62 is fed to the processing locations 54 in order to take up substrate material ablated there and to carry it away via the already formed channel.

The delivery end 66 of the feed line 64 is brought into a delivery position which is adjacent to the processing location 54 in such a way that the delivered fluid reaches the processing location 54 at least proportionally.

The conveying section 60 additionally comprises a reservoir 68 with a conveying pump 70, from which reservoir the feed line 64 is supplied with the inert rinsing fluid 62. In addition, the conveying section 60 comprises a line conveyor 72, with the aid of which the delivery end 66 of the feed line 64 can be tracked to the processing location or the processing locations 54 and can always maintain a suitable delivery position; the corresponding control is effected by the control device 52. In FIG. 3, the line conveyor 72 is illustrated by way of example as a winding reel 74 to wind up or unwind the feed line 64. The line conveyor 72 is only shown schematically in the further figures.

However, a channel section 42 is not yet formed during material removal and a temperature-regulating channel 34.1 is not yet formed after completion of material removal, in contrast to the case in the method according to the disclosed techniques, which will be explained again further below. Rather, only a precursor hollow structure 76 is created, which is delimited by a sheath 78 composed of the modified substrate material 56. Accordingly, FIG. 3 shows only a portion of such a precursor hollow structure 76 during the creating process.

It is only once the sheath 78 composed of the modified substrate material 56 is removed that the desired temperature-regulating hollow structure 22 or specifically the desired temperature-regulating channel 34.1 is provided as a result.

For this purpose, in the known methods, corresponding processing steps, such as etching or heat treatment, for example, are carried out subsequently, i.e., with the processing light beam 46 deactivated after the ablation of the substrate material 12 as of the substrate 12, by which processing steps the sheath 78 is removed.

In contrast thereto, according to the disclosed techniques, in a step (D), a chemically active treatment medium 80 is applied to the processing locations 54 while the substrate material 12a is being ablated at the processing locations 54 in the course of method step (B) being carried out, wherein the chemically active treatment medium 80 at the processing locations 54 exhibits an effect against modified substrate material 58 present there and removes it.

Consequently, firstly, ablated substrate material is rinsed away from the processing locations 54 by the rinsing fluid; secondly, the modified substrate material 56 is removed by the chemically active treatment medium 80, wherein modified substrate material 56 separated as particles, but not yet dissolved, is likewise rinsed away. Overall, the material removal is thus increased by that portion of the modified substrate material 56 which is removed by the chemically active treatment medium 80.

At the same time, the chemically active treatment medium 80 also acts on substrate material ablated by the processing light beam 46, whereby the size of ablation particles is reduced, which counteracts clogging of the temperature-regulating channel section 42 serving as an outflow channel.

In the case of the present exemplary embodiment, the chemically active treatment medium 80 is an etching medium 80′ and the modified substrate material 56 is removed by an etching process. Alternatively, the treatment medium 80 may also be an oxidizing agent or a reducing agent, which also includes that the treatment medium 80 contains an oxidizing agent or a reducing agent.

In this case, either the etching medium 80′ as such may be an etchant with this etching effect or the etching medium 80′ may be an etchant precursor from which an etchant with this etching effect can arise at the processing locations 54, whereby this etchant precursor indirectly exhibits an etching effect. The substance or compound which defines an etchant or an etchant precursor need not be present in a concentration of 100% in the etching medium 80′, but rather need only at least be comprised by the etching medium 80′.

Firstly, temperature-activatable precursors from which an etchant arises above a threshold temperature can be used as etchant precursor. This is then accomplished by the action of heat on account of the temperatures prevailing at the processing locations 54. Alternatively, reaction-activatable precursors can be used, from which the etchant arises by way of a reaction with a reactant at the processing locations 54. If such reaction-activatable precursors are used, such a reactant is applied to the processing locations 54 such that the etchant arises from the precursor at the processing locations. In addition, photoactivatable precursors can be used, from which the etchant arises by way of irradiation with an activation radiation.

Alkalis and acids come into consideration as etching agents. In the case of alkalis, they are in particular strong alkalis, such as for example potassium hydroxide KOH. Strong acids may also be used, though, in the case of acids, hydrofluoric acid HF, which defines a weak but highly reactive acid, is used in particular. Alternatively, an ammonium fluoride buffer NH₄F/H₂O/HF may be used, or for dry etching CF₄.

As a temperature-activatable etchant precursor for the formation of hydrofluoric acid HF as an etchant at the processing locations 54, for example, potassium hydrogen difluoride HKF2 can be used, which reacts at temperatures above about 239° C. according to

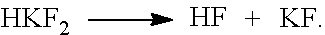

As a temperature-activatable etchant precursor for the formation of hydrofluoric acid HF as an etchant at the processing locations 54, for example, ammonium hexafluorosilicate ((NH₄)₂[SiF₆]) can likewise also be used, which reacts at temperatures above about 100° C. according to

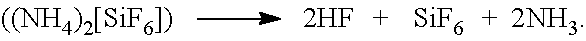

The temperature required for the formation of the etchant from the etchant precursor is achieved in this case at the processing locations 54 by the processing light beam 46, with which the respective temperature-activatable etchant precursor interacts at the processing locations 54.

Reaction-activatable etchant precursors may be for example calcium fluoride CaF₂, sodium fluoride NaF, potassium fluoride KF, lithium fluoride LiF, ammonium hydrogen difluoride NH₄HF₂ or the like, which react with reactants in the form of proton donors such as sulfuric acid H₂SO₄, hydrochloric acid HCl or phosphoric acid H₃PO₄ in the desired manner.

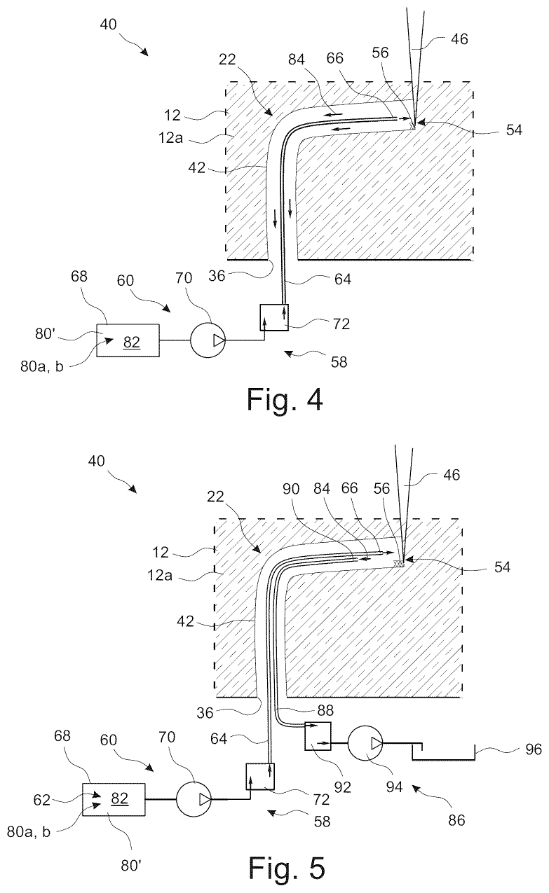

Exemplary embodiments of the processing system 40 and of the method according to the disclosed techniques will now be explained with reference to FIGS. 4 to 8. In the case of all the fluid devices 58 described below, it is assumed here that the installed components are resistant to the fluids and media used and can convey them without impairment or these can be caused to flow through said fluid devices.

In this case, in principle, the fluid device 58 is configured in such a way that the etching medium 80′ can be applied to the processing locations 54 while the focusing device 48, 50 explained above is in operation and the processing light beam 46 is being focused onto the processing locations 54.

FIG. 4 illustrates in this respect a first exemplary embodiment of the processing system 40 and of the method according to the disclosed techniques and the result achieved therewith; use is made of the fluid device 58 described with reference to FIG. 3 with the same components 60 to 74, which however are suitable for conveying the etching medium 80′.

In this case, steps (C) and (D) explained above are combined as it were by the etching medium 80′ being provided by a rinsing fluid 82 comprising the etching medium 80′. The reservoir 68 is thus filled with this rinsing fluid 82. As etching medium 80′, only an etchant or a temperature-activatable precursor or a photoactivatable precursor is considered in this set-up of the fluid device 58. Hereinafter, an etchant is designated by 80a, a temperature-activatable precursor and a photoactivatable precursor are designated by 80b and a reaction-activatable precursor is designated by 80c.

If the etching medium 80′ is an etchant 80a as such, the rinsing fluid 82 forms a dilute acid or alkali.

A collective fluid designated by 84 in its entirety flows away from the processing locations 54. The collective fluid 84 is a mixture of all fluids, media and materials that flow away from the processing locations 54. Accordingly, the collective fluid 84 also entrains etchant 80a, if appropriate. The flow of the collective fluid 84 is indicated by corresponding arrows. The collective fluid 84 flows through the already formed temperature-regulating channel section 42 to the opening 36 thereof and out of the substrate 12 there.

It is possible to exploit the fact that the etching medium 80′ at the processing locations 54 is locally heated by the processing light beam 46. As a result, the etching effect of the etchant 80 as acting at the processing locations 54 can be additionally intensified without already hot etchant 80a having to be guided to the processing locations 54. The concentration of the etching medium 80′ in the rinsing fluid 82 or the concentration of the etchant 80 as which finally reaches the processing locations 54 or arises there can therefore be minimized and coordinated with achieving the required etching effect for ablating the modified substrate material 56 at the temperature attained at the processing locations.

Generally, overall very uniform temperature-regulating channels 34 and generally very uniform temperature-regulating hollow structures 22 can be formed by the method according to the disclosed techniques.

This is assisted by the fact that significant material removal takes place only locally at the processing locations 54, where the etchant 80a present has the required temperature. In the already processed areas through which the collective fluid 84 flows, on account of the lower temperature of the collective fluid 84 there is no or only slight material removal by etchant 80a if the latter is entrained by the collective fluid 84.

FIG. 5 shows a second exemplary embodiment of the processing system 40 and of the method, in which the fluid device 58 supplementarily comprises a suction extraction device 86 comprising a suction extraction line 88 with a suction extraction end 90, a line conveyor 92 and a suction pump 94. The suction extraction device 86 extracts by suction at least a large portion of the collective fluid 84 flowing away from the processing locations 54 and conveys it to a schematically indicated collecting container 96.

In this case, the suction extraction line 88 extends alongside the feed line 64 through the already formed temperature-regulating channel section 42 as far as a suction extraction position at which the suction extraction end 90 is located. With the aid of the associated line conveyor 92, the suction extraction end 90 is tracked.

In this case, the suction extraction position of the suction extraction line 88 is always further away from the processing locations 54 than the delivery position of the feed line 64. In other words, the suction extraction end 90 of the suction extraction line 88 is thus always arranged spatially further upstream of the processing locations 54 than the delivery end 66 of the feed line 64.

What is achieved by this measure more reliably again is that the etchant 80a acts in a targeted manner locally at the processing locations 54 and removes the modified substrate material 56. The already formed temperature-regulating channel section 42 is subjected to no or at least reduced unwanted etching attacks by etchant 80a which, if appropriate, is entrained by the collective fluid 84, since the collective fluid 84 does not flow away via the already formed temperature-regulating channel section 42.

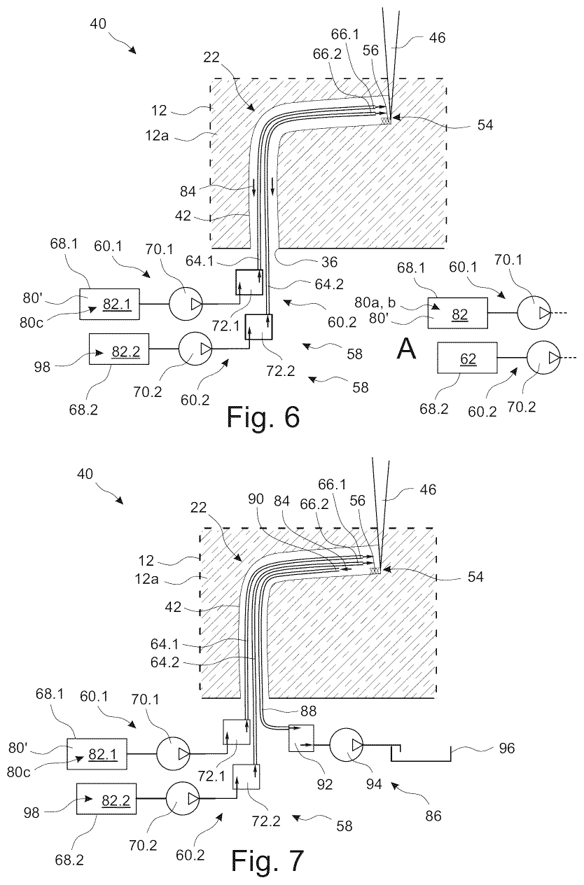

FIG. 6 illustrates the processing system 40 and the method according to a third exemplary embodiment, in which there are two conveying sections 60, which are designated by 60.1 and 60.2 and whose functionally identical components are likewise identified by the respective index 0.1 and 0.2, respectively.

This concept is applied in particular if the etching medium 80′ is a reaction-activatable precursor 80c; the latter is delivered by the first feed line 64.1 to the processing locations 54. A reactant designated by 98, by way of which the etchant 80a at the processing locations 54 arises from the precursor 80c in the desired manner, is delivered by the second feed line 64.2 to the processing locations 54.

In this case, the reaction-activatable precursor 80c is provided by a first rinsing fluid 82.1 and the reactant 98 is provided by a second rinsing fluid 82.2, wherein the first rinsing fluid 82.1 is kept available in the reservoir 68.1, of the first conveying section 60.1 and the second rinsing fluid 82.2 is kept available in the reservoir 68.2 of the second conveying section 60.2.

In order that the desired conversion to the etchant 80a occurs immediately after the emergence of the precursor 80a and the reactant 98 from the respective feed line 64.1 and 64.2, the delivery ends 66.1 and respectively 66.2 and the associated delivery positions are arranged spatially as directly next to one another as possible.

FIG. 6A shows the two reservoirs 68.1, 68.2 with associated conveying pumps 70.1, 70.2 in a modification in which two conveying sections 60.1 and 60.2 are likewise used. In this modification, however, by the first conveying section 60.1, as etching medium 80′ the etchant 80a as such or a temperature-activatable precursor or photoactivatable precursor 80b is delivered with the aid of the rinsing fluid 82 through the first feed line 64.1 to the processing locations 54; the corresponding rinsing fluid 82 is kept available in the reservoir 68.1 of the first conveying section 60.1. In the reservoir 68.2 of the second conveying section 60.2, by contrast, inert rinsing medium 62 is kept available in this modification, whereby inert rinsing fluid 62 is additionally applied to the processing locations 54. In this case, the second conveying section 60.2 defines an inert conveying section.

In this way, for example, the concentration of the etching medium 80′ at the processing locations 54 can be adjusted by a higher or lower delivery of inert rinsing fluid 62 in conjunction with constant delivery of the etching medium 80′ by the rinsing fluid 82 during the ongoing ablation process.

FIG. 7 shows a fourth exemplary embodiment of the processing system 40 and of the method, in which the concept with two conveying sections 60.1, 60.2 is likewise implemented and the suction extraction device 86 is supplementarily provided. In the manner described above, what is supported as a result is that the etching effect of the etchant 80a present at the processing locations 54 takes place so as to be as locally delimited as possible only in the close vicinity of the processing locations 54.

The modification according to FIG. 6A, in which etchant 80a or temperature-activatable precursor or photoactivatable precursor 80b and additionally inert rinsing fluid 62 are applied to the processing locations 54, can likewise be carried out here.

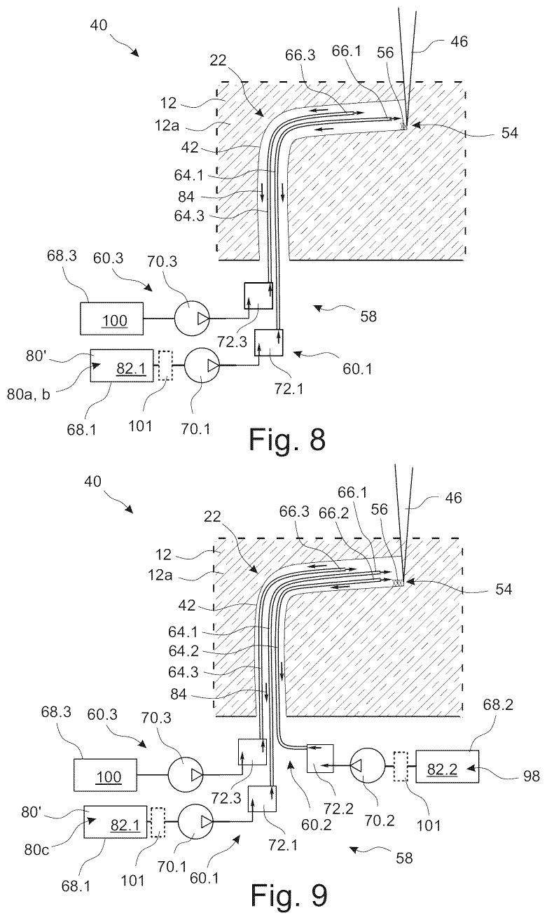

FIG. 8 is a fifth exemplary embodiment of the processing system 40 and of the method, in which such a local delimitation of the etching effect of the etchant 80a is supported by an auxiliary medium 100, which is fed in at a greater distance upstream of the processing locations 54 than the etching medium 80′. In the variant shown in FIG. 8, the etching medium 80′ may be the etchant 80a as such or a temperature-activatable precursor or a photoactivatable precursor 80b.

In general terms, the collective fluid 84 is diluted and/or neutralized with the aid of the auxiliary medium 100.

For this purpose, there is an auxiliary medium conveying section designated by 60.3, in which the same components 64 to 72 correspondingly bear the index 0.3. In this case, the delivery position of the feed line 64.3 is always further away from the processing locations 54 than the delivery position of the feed line 64.1. In other words, the delivery end 66.3 of the feed line 64.3 is thus always arranged spatially further upstream of the processing locations 54 than the delivery end 66.1 of the feed line 64.1.

The auxiliary medium 100 may be for example inert rinsing fluid 62 or a neutralizing medium, which neutralizes the etchant 80a. Depending on the etchant 80a present at the processing locations 54, corresponding alkalis or acids can be used as neutralizing medium.

As a result, the auxiliary medium 100 is applied to an area spatially upstream of the processing locations 54, with said area being rinsed, so that the resulting collective fluid 84 entrains no etchant 80a
or entrains etchant 80a only in a low concentration that gives rise to an etching reaction at the substrate material 12a along the already formed temperature-regulating channel section 42 only to a negligible extent. At the same time, the temperature of the collective fluid 84 is reduced by the incoming auxiliary medium 100, whereby the reactivity of etchant 80a present is supplementarily reduced.

The etching medium 80′ or the rinsing fluid 82 can therefore optionally even be heated by a heating unit 101 shown by dashed lines in FIG. 8, in order to locally increase the etching effect at the processing locations 54. By virtue of the aforementioned cooling by the auxiliary medium 100 thereafter, there is nevertheless no removal of the substrate material 12a along the temperature-regulating channel section 42.

FIG. 9 shows, as a sixth exemplary embodiment of the processing system 40 and of the method, how the concepts in accordance with the third exemplary embodiment according to FIG. 6 and in accordance with the fifth exemplary embodiment according to FIG. 7 can be combined. With the aid of the first conveying section 60.1 and the second conveying section 60.2, reaction-activatable precursor 80c and reactant 98 are applied to the processing locations 54, whereby etchant 80a arises there. By the third conveying section 60.3, the auxiliary medium 100 is delivered spatially upstream of the processing locations 54 in the manner described above and with the effect described.

Here, too, the modification in accordance with FIG. 6A can be carried out for the first and second conveying sections 60.1 and 60.2.

If appropriate, in the variants explained with regard to FIGS. 8 and 9, supplementarily moreover the suction extraction device 86 can be provided and the collective fluid 84, which then also comprises the auxiliary medium 100, can be extracted by suction.

### 3. Substrate Obtained

FIG. 10 then shows once again the substrate 12 in the stage of the carrier substrate 12″ with temperature-regulating hollow structures 22 which were obtained by the method explained above and are again represented by way of example by three temperature-regulating channels 34.1, 34.2 and 34.3. The temperature-regulating hollow structures 22 respectively define an inner lateral surface 102, wherein for the sake of clarity only one inner lateral surface 102 is provided with a reference sign.

There follows an explanation of properties of the temperature-regulating hollow structures 22 or the temperature-regulating channels 34 and the substrate 12 as such which are possible or result when the method described above is applied, wherein optionally properties that have already been described are also taken up again and/or supplemented.

### 3.1 Temperature-Regulating Hollow Structures/Temperature-Regulating Channels

Application of the above-explained method for incorporating the temperature-regulating hollow structures 22 has the effect of obtaining substrates 12 with temperature-regulating hollow structures 22, the inner lateral surface 102 of which has an extremely high quality with an average roughness Ra of between 10.0 μm and 5.0 μm, which in this case may in particular lie between 10.0 μm and 6.5 μm, between 10.0 μm and 8.0 μm, between 8.5 μm and 5.0 μm, between 7.0 μm and 5.0 μm or between 8.5 μm and 6.5 μm, or the inner lateral surface 102 of which has an extremely high quality with an average roughness Ra of 5.0 μm and less, which in this case may lie between 5.0 μm and 0.1 μm, between 4.5 μm and 0.125 μm, between 4.0 μm and 0.15 μm, between 3.5 μm and 0.175 μm or between 3.0 μm and 0.2 μm. In practice, it has been possible in particular to achieve particularly good average roughnesses Ra of between 0.1 μm and 0.5 μm, between 0.15 μm and 0.45 μm, between 0.2 μm and 0.4 μm and between 0.25 μm and 0.35 μm. In principle, however, average roughnesses Ra of between 10.0 μm and 5.0 μm are also a good result.

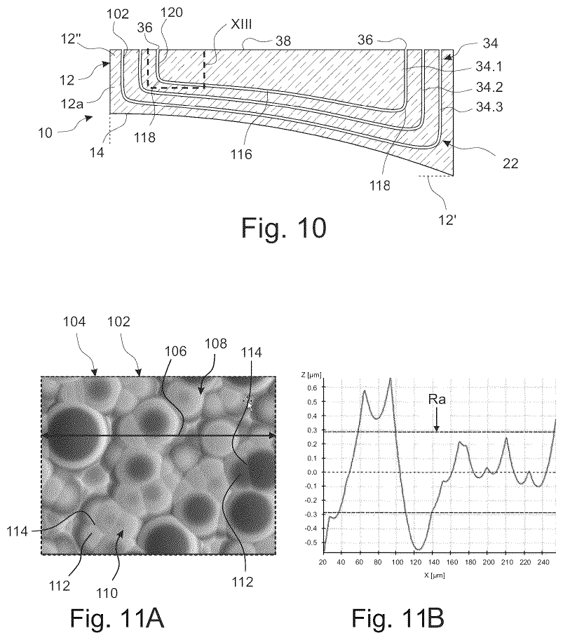

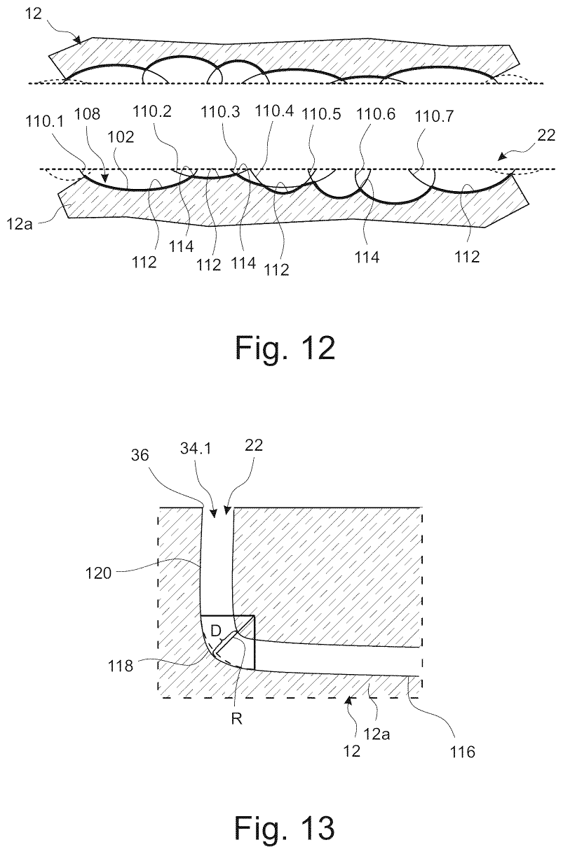

FIG. 11A shows a topography image of a surface area 104 of the inner lateral surface 102 of such a temperature-regulating hollow structure 22 and FIG. 11B shows a section along the section line denoted in FIG. 11A by 106, which illustrates an average roughness Ra achieved there of about 0.28 μm. The surface area 104 has an extent of 254 μm×190 μm.

The average roughnesses Ra are determined and specified in accordance with DIN EN ISO 25178 (as of April 2023). The measurement was performed by a white light interferometer with 50× magnification, as is known per se.

FIG. 11A illustrates that applying the method has the effect of obtaining, at least in surface areas of the inner lateral surface 102 of the temperature-regulating hollow structures 22, a surface topography 108 of which the geometric shape results from an overlaying of sunken structures 110 which extend into the substrate material 12a.

This is additionally illustrated schematically in FIG. 13 on the basis of a longitudinal section of a temperature-regulating hollow structure 22, clearly exaggerated in terms of its proportions and without reference to the images according to FIG. 11A, wherein only the transition at the bottom of FIG. 13 between the temperature-regulating hollow structure 22 and the substrate material 12a is discussed below. By way of example, seven sunken structures 110.1, 110.2, 110.3, 110.4, 110.5, 110.6 and 110.7 extending into the substrate material 12a can be seen there with solid lines.

In FIG. 13, dashed lines illustrate a reference lateral surface from which the sunken structures 108 extend into the substrate material 12a. The overlaying of these sunken structures 110 results then in the surface topography 108, the course of which can be seen with a thicker solid line in the section shown in FIG. 13.

As a result, the surface topography 108 defines mutually adjoining sunken areas 112, between which peripheral regions 114 run. In FIG. 11, only a few such sunken areas and peripheral regions are provided with reference signs.

By way of illustration, these peripheral regions 114 form a kind of mountain ridge between two adjacent valleys in the form of two mutually adjoining sunken areas 112. These peripheral regions 114 may in particular be linear.

The sunken structures 110 may in particular be segments of in themselves point-symmetrical or at least axis-symmetrical bodies, such as for example segments of a sphere, segments of an ellipsoid or paraboloids. The resulting sunken areas 112 may for their part be axis-symmetrical and for example follow a portion of the outer lateral surface of segments of a sphere, segments of an ellipsoid or paraboloids. In this case, their peripheral regions 114 are also axis-symmetrical. However, sunken areas 112 that are not axis-symmetrical, with peripheral regions 114 that are not axis-symmetrical, may also be produced and present, which can be seen in FIG. 11A on the basis of two sunken areas respectively denoted there by 112 and their peripheral regions denoted by 114. The final geometry and dimension of a sunken area 112 surrounded by a circumferential peripheral region 114 depends on the geometries and dimensions of the sunken structures 110, which are understood as the basis for the formation of the sunken area 112. For the sake of completeness, it should be noted that the sunken structures 110 are distributed over the surface area of the lateral surface 102, but FIG. 13 can of course only show the section shown and no sunken structures 110 and resulting sunken areas 112 in front of and behind the plane of the paper.

A temperature-regulating channel 34 may have diameters of between 0.5 mm and 20 mm, with diameters of between 1 mm and 5 mm preferably being formed.

The length of a temperature-regulating channel 34 depends primarily on the dimension of the substrate 12 and in practice is at least 10 cm, but may also be at least 15 cm or at least 20 cm.

A temperature-regulating channel 34 may be curved or at least have curved portions. As can be seen in FIG. 22, the temperature-regulating channels 34 in a middle portion 116 thereof follow the curvature of the carrier surface 14, this middle portion 116, which is consequently already a curved portion, extending between two strongly curved portions 118. In FIG. 22, the middle portion 116 and the strongly curved portions 118 are only denoted by a reference sign in the case of the temperature-regulating channel 34.1. The middle portion 116 denoted there opens in FIG. 22 to the left into the strongly curved portion 118 there, which for its part goes over into a straight portion 120, which then ends at the opening 36 of the temperature-regulating channel 34.1. FIG. 13 shows the detail XIII of FIG. 10 on an enlarged scale.

A strong curvature should be understood as meaning angles of curvature of between 60° and 120°, in particular between 80° and 100°, preferably of about 90°. Preferably, a portion 116 of the temperature-regulating channel 34 extends between two strongly curved portions 118 with an angle of curvature of about 90°, as shown in the case of the present exemplary embodiment.

The curvature of a strongly curved portion 118 in this case generally follows an arc. With a 90° curvature for example, there are not two strictly perpendicular portions of the channel.

An outer radius of curvature R and the diameter D of a strongly curved portion, here the strongly curved portion 118, also illustrated in FIG. 13, define a ratio R/D. Preferably, such a ratio R/D lies between 2 and 6, more preferably between 2.5 and 5, and in particular preferably between 2.5 and 3.5. These ratios R/D are not reflected by FIG. 13 or the other figures; to allow this to be seen better, the temperature-regulating channel 34.1 is shown schematically with a proportionally larger diameter.

Relative to the carrier surface 14 of the substrate 12, a temperature-regulating channel 34 runs in particular at a distance of 1.0 mm to 50.0 mm, of 1.0 mm to 20.0 mm, of 1.0 mm to 10.0 mm or of 1.0 mm to 5.0 mm. The distance is in this case preferably determined relative to a normal to the carrier surface 14. In this case, the distance between the temperature-regulating channel 34 and the carrier surface 14 along its course may be different.

### 3.2 Substrate

The method explained above is used to obtain a substrate 12 provided with temperature-regulating hollow structures 22 and with a carrier surface 14 of which the surface figure has a significant stability over time. With a lifetime of the substrate 12 of up to 10 years, at least up to five years and at least up to two years, the surface figure of the carrier surface 14 changes by less than 100 pm, in particular by less than 50 pm and further in particular by less than 25 pm.

This stability of the surface figure is also retained in the case of a mirror 10, which comprises a substrate 12 produced by the methods explained above and is provided with the coating 16. Consequently, a mirror 10 is obtained such that, with a lifetime of the mirror 10 of up to 10 years, at least up to five years and at least up to two years, its surface figure changes by less than 100 pm, in particular by less than 50 pm and further in particular by less than 25 pm.

The high stability of the surface figure of the carrier surface 14 of the substrate 12 and the surface figure of the mirror 10 produced from it is achieved in that the modified substrate material 56 is precisely and purposefully removed, so that a substrate which is particularly homogeneous in itself in terms of its microstructure is obtained or restored after the microstructure no longer has this microstructure homogeneity when the modified substrate material 56 is still present.

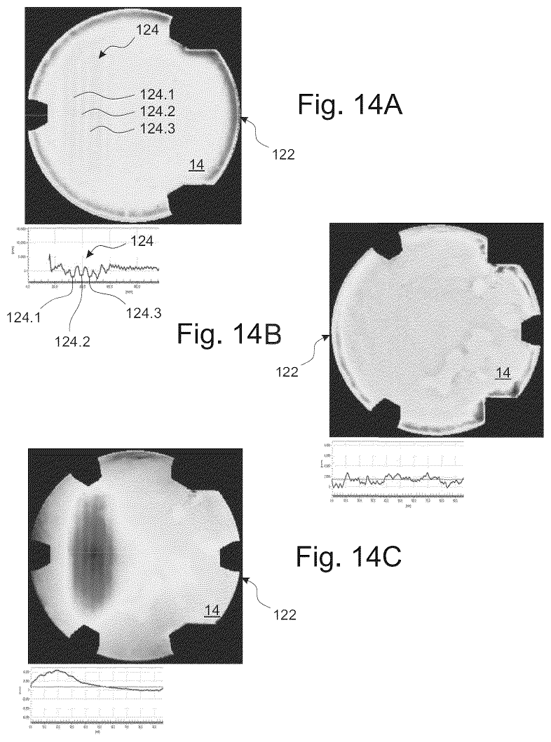

This is reflected by the presentations in FIGS. 14A, B and C of the results of measurements of the surface figure of the carrier surface 14 of a substrate 122 for a mirror, with a surface-image representation of the carrier surface 14 being shown in each case at the top and a deviation profile along a measuring section shown thereunder.

The measurements were carried out using an interferometric measurement system which is based on a Fizeau interferometer and provides a repeatability of 10 pm RMS and a pixel size of typically 0.12 mm×0.12 mm.

FIG. 14A shows the surface figure of the carrier surface 14 for a substrate 122 in which the modified substrate material 56 is still present, which corresponds somewhat to the configuration of the substrate 12 according to FIG. 3, such as is achieved with previously known methods. Depressions 124 in the carrier surface 14 are shown, of which three depressions are denoted by 124.1, 124.2 and 124.3 in the surface-image representation and the deviation profile. These depressions 124 are present where, below the carrier surface 14, the modified substrate material 56 is present in the substrate material 12a. As can be seen in FIG. 14A, the depressions 124 follow the courses of the modified substrate material 56, which in this case can be seen as straight-line channels. The measuring section of the respective deviation profile of FIGS. 14A, B and C runs transversely to the channels.

For comparison purposes, the substrate 122 is not provided with corresponding channels with modified substrate material 56 under the full carrier surface 14; the area to the right of the depressions 124 is unprocessed.

The depressions 124 are produced due to the microstructure inhomogeneities in the substrate material 12a that have been produced there below the carrier surface 14 by the modified substrate material 56

FIG. 14B shows the surface figure of the carrier surface 14 in the case of a substrate without the modified substrate material 56, which corresponds to the configuration of the substrate 12 according to FIG. 10. As FIG. 14B shows and becomes clear on the basis of the deviation profile, there are significantly smaller depressions 124 there, and the carrier surface 14 then overall has a lower surface figure deviation.

FIG. 14C shows a representation of the differences in the measurements according to FIGS. 14A and 14B and in this context also illustrates the largely unchanged areas of the carrier surface 14 without underlying temperature-regulating hollow structures 22.

In any case, the surface figure measured according to FIG. 14B has the stability over time explained above, which is also achieved for a substrate obtained by the method described here.

### 4. Semiconductor Technology Apparatus/Projection Exposure Apparatus

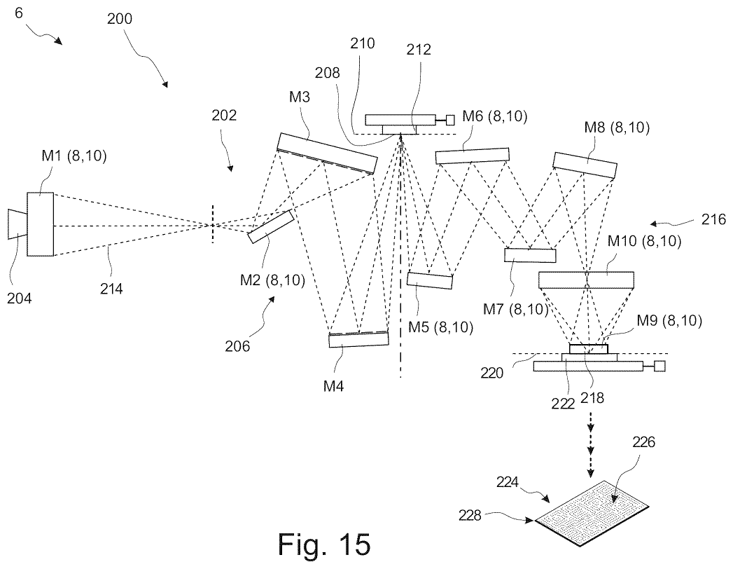

FIG. 15 illustrates once again a semiconductor technology apparatus 6 on the basis of the example of a projection exposure apparatus 200 for EUV semiconductor lithography. Other semiconductor technology apparatuses such as, e.g., a mask inspection apparatus or a wafer inspection apparatus contain components in part identical or similar to those as explained here on the basis of the example of the EUV projection exposure apparatus 200.

The projection exposure apparatus 200 comprises an illumination system 202 with a radiation source 204 and an illumination optical unit 206 for illuminating an object field 208 in an object plane 210, in which a reflective reticle 212 is arranged. In the exemplary embodiment illustrated, the radiation source 204 is an EUV radiation source which emits EUV radiation as working radiation 214, in particular in a wavelength range of between 5 nm and 30 nm. The radiation source 204 can be a plasma source, for example an LPP (laser produced plasma) source or a GDPP (gas discharge produced plasma) source. Alternatively, a synchrotron-based radiation source or a free electron laser (FEL) can be used as the radiation source 204.

Moreover, the projection exposure apparatus 200 comprises a projection optical unit 216 for imaging the object field 208 into an image field 218 situated in an image plane 220 of the projection optical unit 216. As an example of an object 222, a wafer bearing a light-sensitive layer (referred to as a resist) is arranged in the image plane 220. Components for synchronously moving the reticle 212 and the wafer 222 are merely indicated in FIG. 15 and are not provided with reference signs.

The projection exposure apparatus 200 comprises a plurality of optical elements 8 in the form of mirrors Mn, which are consecutively numbered in accordance with their arrangement in the beam path of the projection exposure apparatus 200. In the present case, a total of 10 mirrors M1 to M10 are present in the beam path.

The mirrors M3 and M4 are embodied as facet mirrors containing a multiplicity of individual mirrors. Each of the other mirrors Mn is a mirror 10 with a monolithic mirror substrate 12 and a coating 16 borne thereby, as shown by way of example in FIG. 1. These mirrors are indicated as parallelepipeds in FIG. 15 for the sake of simplicity. In reality, however, the surfaces of the mirrors 10 that are exposed to the EUV radiation 214 and provided with the coating 16 are not plane, but rather curved, as likewise illustrated by FIG. 1.

The mirrors M1 to M4 in the illumination system 206 serve to illuminate a section of the reticle 212 with the desired illumination angle distribution. The mirrors M5 to M10 of the projection optical unit 216 image this section onto the wafer 222 in a reduced size. As a result, the structures contained in the reticle 212 are imaged onto the light-sensitive layer borne by the wafer 222.

With the aid of the optical elements 8, which in the present exemplary embodiment are formed as mirrors 10 for the EUV projection exposure apparatus 200 and the coating of which is configured at least to reflect at least 50% of EUV light impinging with normal or almost normal incidence, the object 222 is irradiated with the working radiation 214.

The semiconductor technology apparatus 6 is part of a production process which can be used to produce a structured electronic component 224, which is shown in FIG. 15 schematically with produced structures 226 as the result of an overall production process comprising even further steps besides the process in the semiconductor technology apparatus 6. What is relevant here, however, is that the semiconductor technology apparatus 6 comprises at least one optical element 8 which was produced in one of the ways encompassed by the method variants explained above.

The structured electronic component 224 is in particular a computer chip 228, during the production of which a projection exposure apparatus, here the projection exposure apparatus 200, is used, as was discussed in the introduction.

### 5. Concluding Remarks

All of the methods, steps, sequences, concepts and principles above can be combined with one another, which is also reflected in the combinations of features specified in the claims.

### 6. General and Additional Aspects

General and additional aspects of the disclosed techniques are described with reference to the following clauses:

1. A substrate for producing an optical element, in particular for producing a mirror (10) for an EUV projection exposure apparatus, wherein the substrate (12) has temperature-regulating hollow structures (22), in particular temperature-regulating hollow structures (22) incorporated into the substrate (12) in accordance with the method as specified in any of claims 1 to 9, characterized in that:
at least one temperature-regulating hollow structure (22) defines an inner lateral surface (102) which has, at least in some areas, an average roughness Ra in accordance with DIN EN ISO 25178, as of April 2023, of between 10.0 μm and 5.0 μm, which in particular lies between 10.0 μm and 6.5 μm, between 10.0 μm and 8.0 μm, between 8.5 μm and 5.0 μm, between 7.0 μm and 5.0 μm or between 8.5 μm and 6.5 μm, or which has, at least in some areas, an average roughness Ra of 5.0 μm and less, which in particular lies between 5.0 μm and 0.1 μm, between 4.5 μm and 0.125 μm, between 4.0 μm and 0.15 μm, between 3.5 μm and 0.175 μm or between 3.0 μm and 0.2 μm.

2. A substrate for producing an optical element, in particular for producing a mirror (10) for an EUV projection exposure apparatus, wherein the substrate (12) has temperature-regulating hollow structures (22), in particular temperature-regulating hollow structures (22) incorporated into the substrate (12) in accordance with the method as specified in any of claims 1 to 9, characterized in that:
at least one temperature-regulating hollow structure (22) defines an inner lateral surface (102) which has a surface topography (108) of which the geometric shape results from an overlaying of sunken structures (110) which extend into a substrate material (12a) of the substrate (12).

3. The substrate as specified in clause 2, characterized in that one or more sunken structures (110) are segments of in themselves point-symmetrical or at least axis-symmetrical bodies.

4. The substrate as specified in clause 2 or 3, characterized in that the surface topography (108) defines mutually adjoining sunken areas (112), between which peripheral regions (114), in particular linear peripheral regions (114), run.

5. The substrate as specified in clause 4, characterized in that one or more sunken areas (112) are axis-symmetrical or not axis-symmetrical.

6. The substrate as specified in clause 5, characterized in that an axis-symmetrical sunken area (112) follows a portion of the outer lateral surface of a segment of a sphere, a segment of an ellipsoid or of a paraboloid.

7. The substrate as specified in any of clauses 1 to 6, characterized in that at least one temperature-regulating hollow structure (22) is a temperature-regulating channel (34), which has one or more of the following features:
a) the temperature-regulating channel (34) has a diameter of between 0.5 mm and 20 mm, preferably between 1 mm and 5 mm;
b) the temperature-regulating channel (34) has a length of at least 10 cm, at least 15 cm or at least 20 cm;
c) the temperature-regulating channel (34) is curved or has at least one curved portion (116; 118);
d) the temperature-regulating channel (34) has a portion (116) which follows the curvature of a carrier surface (14) for a coating (16) of the substrate (12);
e) the temperature-regulating channel (34) has a strongly curved portion (118) which has an angle of curvature of between 60° and 120°, in particular between 80° and 100°, preferably of about 90°;
f) the temperature-regulating channel (34) has a strongly curved portion (118) which has an angle of curvature of between 60° and 120°, in particular between 80° and 100°, preferably of about 90°, and follows an arc;
g) the temperature-regulating channel (34) has a strongly curved portion (118) which has an angle of curvature of between 60° and 120°, in particular between 80° and 100°, preferably of about 90°, and follows an arc and defines an outer radius of curvature R and a diameter D, wherein a ratio R/D of the radius of curvature R to the diameter D lies between 2 and 6, preferably between 2.5 and 5 and in particular preferably between 2.5 and 3.5;
h) the temperature-regulating channel (34) is at a distance relative to a carrier surface (14) for a coating (16) of the substrate (12) of 1.0 mm to 50.0 mm, of 1.0 mm to 20.0 mm, of 1.0 mm to 10.0 mm or of 1.0 mm to 5.0 mm.

8. A substrate for producing an optical element (8), in particular for producing a mirror (10) for an EUV projection exposure apparatus, which substrate has temperature-regulating hollow structures (22), in particular temperature-regulating hollow structures (22) incorporated into the substrate (12) in accordance with the method as specified in any of clauses 1 to 9, and defines a carrier surface (14) for a coating (16), characterized in that:
with a lifetime of the substrate (12) of up to 10 years, at least up to five years and at least up to two years, the surface figure of the carrier surface (14) changes by less than 100 pm, in particular by less than 50 pm and further in particular by less than 25 pm.

9. A substrate with the features as specified in clause 23 and with the features as specified in at least one of clauses 2 to 7.

10. A substrate with the features as specified in clauses 8 and 9.

11. The substrate as specified in any of clauses 1 to 10, characterized in that temperature-regulating hollow structures (22) are incorporated in accordance with the method as specified in any of claims 1 to 9.

12. An optical element, in particular a mirror (10) for an EUV projection exposure apparatus, comprising a substrate (12), characterized in that the substrate (12) is a substrate (12) as specified in any of clauses 1 to 10.

13. An optical element, in particular a mirror (10) for an EUV projection exposure apparatus, with a substrate (12), in particular an optical element as specified in clause 34, characterized in that, with a lifetime of the optical element of up to 10 years, at least up to five years and at least up to two years, the surface figure of the optical element (8) changes by less than 100 pm, in particular by less than 50 pm and further in particular by less than 25 pm.

14. The optical element as specified in either of clauses 12 and 13, characterized in that the optical element (8) is a mirror (10) for an EUV projection exposure apparatus, wherein the substrate (12) has a carrier surface (14) bearing a multilayer coating (16) configured at least to reflect at least 50% of EUV light impinging with normal or almost normal incidence.

15. The optical element as specified in clauses 14 and 13 and 12.

16. A semiconductor technology apparatus, in particular an EUV projection exposure apparatus (200), a mask inspection apparatus or a wafer inspection apparatus, in which an object (222) is irradiatable with a working radiation (214) with the aid of at least one optical element (8), characterized in that the optical element (8) is an optical element (8) as specified in any of clauses 12 to 15.

17. The apparatus as specified in clause 16, characterized in that the apparatus (6) is an EUV projection exposure apparatus (200) and in that the at least one optical element (8) is a mirror (10) as specified in clause 14.

18. A structured electronic component, characterized in that the structured electronic component (224) was produced with the aid of a semiconductor technology apparatus (6) as specified in clause 16 or 17 and using at least one optical element (8) as specified in any of clauses 12 to 15.

What is claimed is:

1. A method for incorporating temperature-regulating hollow structures into a substrate for a mirror for an EUV projection exposure apparatus, comprising:
providing a substrate consisting of a substrate material;
progressively focusing a processing light beam onto processing locations at which temperature-regulating hollow structures are intended to arise, so that the substrate material is ablated at the processing locations, wherein adjacent to the processing locations modified substrate material arises, the modified substrate material having an increased susceptibility to a chemically active treatment medium relative to the substrate material;
applying the treatment medium to the processing locations while progressively focusing the light beam onto the processing locations, wherein the treatment medium exhibits an effect at the processing locations and removes modified the substrate material present there; and
applying a rinsing fluid to the processing locations while progressively focusing the light beam onto the processing locations such that ablated substrate material is rinsed away.

2. The method of claim 1, wherein the treatment medium comprises an etching medium, an oxidizing agent or a reducing agent.

3. The method of claim 1, wherein the treatment medium comprises an etchant or etchant precursor from which an etchant can arise at the processing locations.

4. The method of claim 3, wherein the etchant precursor comprises a temperature-activatable precursor, a reaction-activatable precursor or a photoactivatable precursor.

5. The method as claimed in claim 2, wherein the etching medium comprises:
an etchant comprising hydrofluoric acid HF or potassium hydroxide KOH;
or
an etchant precursor comprising potassium hydrogen fluoride HKF₂, ammonium hexafluorosilicate (NH₄)₂[SiF₆], calcium fluoride CaF₂, sodium fluoride NaF, potassium fluoride KF, lithium fluoride LiF, or ammonium hydrogen difluoride NH₄HF₂.

6. The method of claim 1, wherein the treatment medium is provided by the rinsing fluid.

7. The method as claimed in claim 6, wherein the treatment medium is an etching medium and
the rinsing fluid provides the etching medium as an etchant, as a temperature-activatable etchant precursor from which an etchant arises above a threshold temperature, or as a photoactivatable etchant precursor from which an etchant arises by way of irradiation with an activation radiation;
or
the rinsing fluid is a first rinsing fluid, which provides a reaction-activatable etchant precursor from which etchant can arise at the processing locations by way of a reaction with a reactant, and the reactant is provided by a second rinsing fluid.

8. The method of claim 6, further comprising applying an inert rinsing fluid to the processing locations.

9. The method of claim 6, wherein collective fluid flowing away from the processing locations is extracted by suction with via a suction extraction device.

10. The method of claim 6, wherein fluid flowing away from the processing locations is diluted and/or neutralized via an auxiliary medium.

11. A processing system for incorporating temperature-regulating hollow structures into a substrate of a mirror for an EUV projection exposure apparatus configured to implement the method of claim 1, the processing system comprising
a light source configured to generate the processing light beam;
a focusing device configured to focus the processing light beam onto the processing locations at which the temperature-regulating hollow structures are intended to arise;
a fluid source configured to apply the rinsing fluid to the processing locations and apply the treatment medium to the processing locations.

12. The processing system of claim 11, wherein the treatment medium comprises an etching medium, an oxidizing agent or a reducing agent.

13. The processing system of claim 11, wherein the treatment medium comprises an etchant or an etchant precursor from which an etchant can arise at the processing locations.

14. The processing system of claim 12, wherein the etching medium comprises an etchant comprising hydrofluoric acid HF or potassium hydroxide KOH, or the etching medium comprises an etchant precursor comprising potassium hydrogen fluoride HKF₂, ammonium hexafluorosilicate (NH₄)₂[SiF₆], calcium fluoride CaF₂, sodium fluoride NaF, potassium fluoride KF, lithium fluoride LiF, or ammonium hydrogen difluoride NH₄HF₂.

15. The processing system of claim 11, wherein the fluid source comprises a conveying section with a feed line, which has a delivery end and is connected to a reservoir in which the rinsing fluid is kept available.

16. The processing system of claim 15, wherein the treatment medium comprises an etching medium; and wherein:
the rinsing fluid provides the etching medium as an etchant, as a temperature-activatable etchant precursor from which an etchant arises above a threshold temperature, or as a photoactivatable etchant precursor from which an etchant arises by way of irradiation with an activation radiation;
or
the conveying section is a first conveying section and the rinsing fluid defines a first rinsing fluid, which provides a reaction-activatable etchant precursor from which etchant can arise at the processing locations by way of a reaction with a reactant, and the processing system further comprising a second conveying section with a second feed line, which has a second delivery end and is connected to a second reservoir, in which a second rinsing fluid is kept available, which provides the reactant.

17. The processing system of claim 15, wherein the fluid source comprises an inert conveying section with a feed line, which has a delivery end and is connected to a reservoir in which an inert rinsing fluid is kept available.

18. The processing system of claim 15, wherein the conveying section comprises a line conveyor configured to track the delivery end of the feed line to the processing locations.

19. The processing system of claim 15, wherein the fluid source comprises a suction extraction device with a suction extraction line, a suction extraction end, and a suction pump connected to the suction extraction end, the suction extraction end configured to extract fluid flowing away from the processing locations by suction.

20. The processing system of claim 19, wherein the suction extraction device comprises line conveyor configured to track the suction extraction end to the processing locations.

21. The processing system of claim 15, wherein the fluid source comprises an auxiliary medium conveying section with an auxiliary medium feed line, and a delivery connected to a reservoir in which an auxiliary medium is kept available which can neutralize the treatment medium.

22. The processing system of claim 21, wherein the auxiliary medium conveying section comprises a line conveyor configured to track the delivery end.

23. A method or claim 1, further comprising:
one or more steps of chemical and/or physical processing of at least one surface of the substrate; and
producing or applying a coating on the substrate, the coating configured to reflect at least 50% of EUV light impinging with normal or almost normal incidence.

24. A substrate produced according to the method of claim 1, wherein:
the substrate defines a carrier surface for a coating; and
the substrate has a lifetime of two or more years during which a surface figure of the carrier surface changes by less than 100 pm.

25. A mirror for an EUV projection exposure apparatus comprising a substrate as claimed in claim 24, characterized in that, wherein during a lifetime of the mirror of two or more years, a surface figure of the mirror changes by less than 100 pm.

26. The mirror of claim 25, wherein the substrate has a carrier surface bearing a multilayer coating configured at least to reflect at least 50% of EUV light impinging with normal or almost normal incidence.

27. An EUV projection exposure apparatus, a mask inspection apparatus or a wafer inspection apparatus, comprising a mirror as claimed in claim 25.
